(19) United States
(12) Patent Application Publication
(10) Pub. No.: US 2012/0299441 A1
(43) Pub. Date: Nov. 29, 2012

(54) PROCESS FOR PRODUCING ELECTRIC CIRCUITS ON A GIVEN SURFACE

(76) Inventor: Fabio Cappelli, Montebelluna (TV) (IT)

(21) Appl. No.: 13/575,214

(22) PCT Filed: Apr. 7, 2011
(86) PCT No.: PCT/IB2011/051495

§ 371 Date: Jul. 25, 2012

(30) Foreign Application Priority Data
Apr. 8, 2010 (IT) BO2010A000212

(51) Int. Cl. H01L 41/193; H01B 1/04; H02N 2/18; H02N 2/02; H01B 1/12; B05D 3/06; B82Y 30/00

(52) U.S. Cl. 310/317; 252/500; 252/511; 252/62.9 R; 252/62.9 PZ; 252/519.34; 427/532; 427/555; 310/339; 977/734; 977/773

(57) ABSTRACT

A compound (2), and a process to polarize it, are described able to form conductive or isolating tracks. The compound comprises a substrate of solvent, and a dispersion in the substrate. The dispersion comprises (i) a polymer (M) with double covalent conjugated bond, that is to say a heterocyclic compound formed of n atoms of carbon and an atom of a different type linked in a loop structure; and (ii) functionalising elements (Q1) of the polymer, so that the state of the polymer changes from insulator to conductor and vice versa when struck by an electromagnetic field.

The invention relates mainly to a procedure for making conductor circuits and/or electrical charge generators in the form of a signal or current, on any surface and to the electrical circuits made using such procedure.

It is known that to wire surfaces or systems is an expensive and laborious operation. Not only is a huge length of cable used, but its cost and weight often significantly affect the finished product, sometimes even making its production unadvisable.

The invention sets out to resolve this problem for example in the residential sector or in the car industry or in other sectors.

The object of the invention is therefore to realise a system for transmitting signals or commands, in voltage and/or under current from one point to another of a wall or surface of a home, car, boat or whatever else without the need to install in said walls or surfaces electrically insulated electricity conductor wires or cables or commands.

Another object is, in case, to generate signals or commands, in voltage and/or current, without the need to install wires or cables or commands.

Such objects are achieved by a compound according to the appended claim 1. The specific structure of the compound enables its easy and reliable polarisation and depolarisation so as to selectively create conductor or insulating paths within it.

The invention proposes for such purpose a polarisation method according to claim 11.

The compound can be applied in liquid or gel form directly to a medium or applied by means of a separate film or rigid or flexible support layer.

Another form of use is a touch or pressure-sensitive contact layer for an operator, as per claim 23.

Methods of exploiting the electrical specifications of the compound, such as the generation of electricity or mechanical vibrations (see claim 18 or 24) form part of the invention.

All the dependent claims define advantageous embodiments.

The characteristics and advantages of the invention will be more clearly evident from the following description of a preferred embodiment, shown by way of example in the appended drawings, wherein:

FIG. 1 shows a succession of layers of paint for a surface provided with a conductive paint according to the invention;

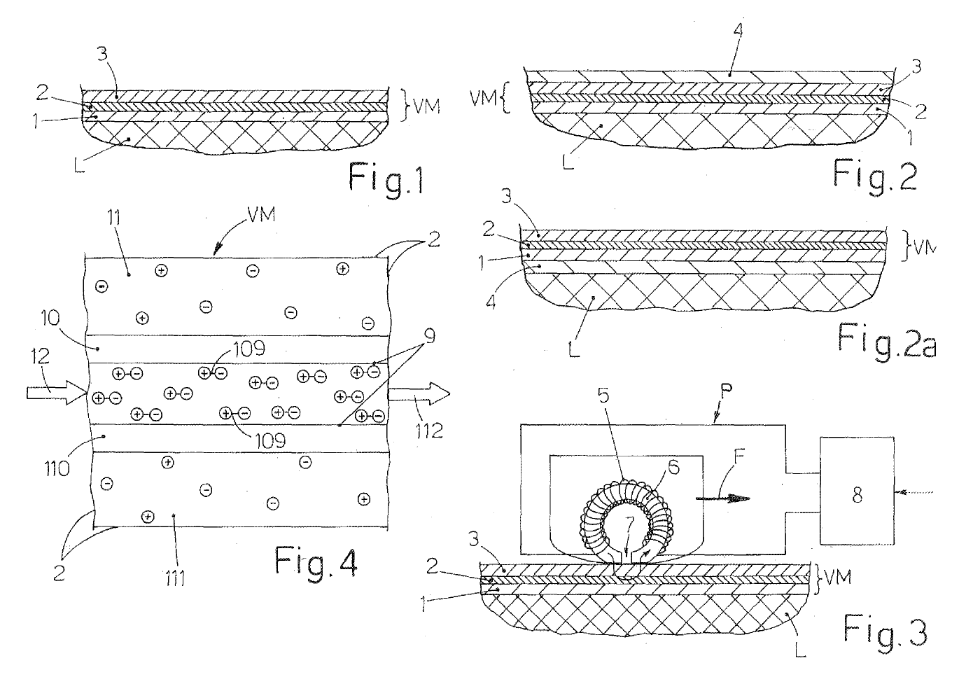

FIGS. 2 and 2a shows layers of paint with the use of a finishing paint;

FIG. 3 schematically illustrates the process and means for polarising the surface treated with the paint according to the invention, so as to make paths or sectors of it conductive;

FIG. 4 schematically illustrates the physical result of the polarising step as in FIG. 3, on the layer of paint;

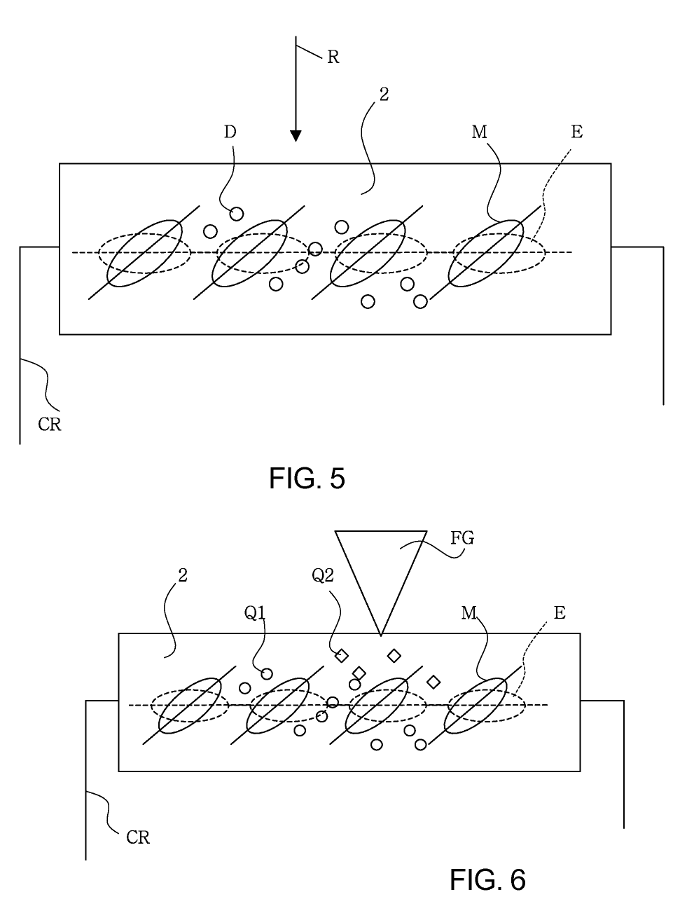

FIGS. 5 and 6 schematically illustrate in cross-section a layer of charged paint.

With reference to FIG. 1 the process for making the electrical circuits or paths on the paintable surface of a medium L composed of a metal laminate or other material will now be described.

At least one layer 1, of a suitable thickness, of any paint with an enhanced adhesion function is deposited on the surface of the medium L, which may be used to eliminate any slight porosities and electrically insulate it, including in relation to the greater or lesser conductive or insulating nature of said surface L.

If the surface L is a metallic sheet, the layer 1 may be about 0.0001-1 mm thick, while if said surface L is not very conductive, for example wood, plastic, resin or another material which is a poor conductor of electricity or electrically insulating, the layer 1 may be of limited thickness, to the order of 0.001-0.7 mm.

It is clear that the reduced thicknesses are compatible with spray applications of the paint and that they may vary depending on the painting techniques used. For example, if the layer 1 is applied using a roller, the thicknesses of such layer will be compatible with those which can be obtained using such painting method.

On the base layer 1 at least one second layer of paint 2 containing the metallic oxides is applied. These oxides are important because as will be explained below, they make electrons available in the matrix.

Note that the layer 2, which contains in dispersion all the elements which we will describe below, may generally be a solvent, preferably aromatic. In particular, the use of a benzene is preferred, and preferably a dichlorobenzene (because it dissolves the Thiophene well), a dichloromethane or nitro-type diluent.

Together with the metallic oxides there may be a further component such as, for example, a graphite. Graphites are excellent dopants, mainly because of their elevated electrical conductivity. In addition they give the overall layer 2 the property of being oily, that is of always maintaining a certain fluidity, without ever drying.

As a result, exposure to UB rays for example will not cause it to flake even after many years. Particular graphite sub-families which have proven extremely advantageous, because said qualities are accentuated, are fullerene and graphene.

The metallic oxides can be freely dispersed in a random manner within a matrix of, for example, vinyl acetate or vinyl-esther based paint.

Alternatively, the metal oxides can also be dispersed in a polymer matrix with double covalent conjugated bond, that is to say heterocyclic compounds, formed of n atoms of carbon and an atom of a different type linked in a loop structure.

One advantageous family of these polymers is Butadiene, which has a very stable molecule.

Another advantageous family of polymers is Thiophene, which substitutes the vinyl. The Thiophene molecules have the distinctive property, as will be seen below, of positioning themselves in a laminar manner, that is all over a plane without overlapping. Moreover, the atom of sulphur of the Thiophene has many electronic affinities with the matrix. In fact, Thiophene has a free atom of Sulphur which acts as a bonding agent between the monomeric chains during the polymerisation phase.

Thiophene and Butadiene may even be mixed together in the matrix.

The aforesaid polymers and the graphites can co-operate together in the matrix with the metal oxides. Note however that one or more of said polymers can also be used on its own in the matrix without the help of the oxides and/or in place of them (everything else described for the rest of the substrate remaining valid).

Ferric chloride or aluminium chloride, with or without colour pigments, can be added to the metallic oxides plus the polymers or when they are used on their own to only one of the two. Such chlorides are highly doping, and are convenient both because they eliminate a hysteretic phenomenon of which more will be said below, and because they have a marked ability to release/accept electrons. In particular, the ferric chloride or aluminium chloride are oxides dissolved in chlorine which dissolve well in Thiophene, which is a plastic. The excellent homogenisation ensures optimal communication at an electronic level, favouring the interchange of electrons towards the polymer (e.g. Thiophene).

The metal oxides may, for example, be composed of iron oxides in the formulation Fe₂O₃, or Fe₃O₄ or even better, for their improved magnetisation/saturation curve, of chrome oxides or dioxides, in the formulation CrO₂.

The metallic oxides, with any graphite, and/or any polymers will be dispersed in the matrix or substrate of paint in proportionate quantities to the type of current or electronic signal which said paint must conduct. By way of a non-limiting example, a dispersion in the proportion of about 1350 cm³ of metallic oxides with any graphite per square metre of paint may be supposed and it should be possible to apply the paint thus obtained by spraying, using a roller or by other known methods. Excellent results can also be achieved using metallic oxides with any graphites, in nanostructure forms.

If the layer 2 is applied by spraying, then it may have an indicative thickness of 0.001-1 mm, while if applied using a roller or other techniques, such layer may be thicker. At least one finishing layer 3 is applied over the layer 2.

This third layer 3 may be applied by spraying, with a roller or using another technique, in that it may vary in thickness from 0.01 to 1 mm (see below). The layer 3 may be formed of the same vinyl or polymer matrix (as described above) and/or by any product such that said layer 3 has good protective properties from atmospheric agents and good outward electrical insulation properties.

On the multilayer paint surface VM made as in FIG. 1 the finishing paint 4 may be applied according to client specifications (FIG. 2), finding in the upper layer 3 of said paint surface VM, a valid enhanced adhesion surface.

There is nothing, however, to prevent the multilayer paint VM treatment from being applied to the medium L already provided with the finishing paint 4 described above, as illustrated in FIG. 2a. In this case the multilayer paint surface VM may be transparent or coloured, and may be applied in the form of a film in strips, islands or other shapes, including for decorative, and/or ornamental purposes. The multilayer VM surface is like a film to be applied to any medium.

After the painting step described above, linear paths or polarised zones are made in the intermediate layer of paint 2 containing the metallic oxides with any graphite, electrically conductive to and electrically insulated from the neighbouring areas, along which electrical charges in the form of current, voltage or signal are then made to transit.

For this step a laser or polariser P as in the example in FIG. 3 may be used, provided with at least one reel 5 wound on a ferromagnetic nucleus 6 with an air gap 7 and connected to an oscillator 8 generating the voltage and frequencies suitable for the purpose.

The polariser P has good portable and handling characteristics and can be powered either by its own batteries or with the help of the external electricity supply. The polariser P must be able to supply a zero frequency magnetic field to the poles of its air gap 7, achievable with a DC supply or with a variable frequency to the order of 16 KHz or more (see below).

By bringing the air gap 7 of the polariser P close to the multilayer paint surface VM, as illustrated in FIG. 3, it is possible to induce an electromagnetic field in the intermediate layer 2 with the metal oxides and/or polymers and any graphite, able to create in said layer 2 areas with sequences of orientated dipoles with a variable ohmic resistance depending on the type of polarisation imposed from the outside and in relation to the type of oxide with any graphite used in such layer 2 which may vary from several ohm to thousands of ohm.

By making the head 5,6 of the polariser P transit over the painted surface VM, for example in the direction of the arrow F in FIG. 3, at a variable and predefined speed depending on the type of application of the invention, at least one path 9 directly influenced by the magnetic field will be created in the layer 2 (see FIG. 4), characterised by the presence of orientated dipoles 109 of the metallic oxides with any graphite, also coming from zones 10,110 neighbouring said path 9, which will be charge-free and of a part of the metallic oxides with any graphite, which given the action of the magnetic field of polarisation have migrated in the path 9.

Zones 10 and 110 will create all around the main path 9, dead zones with a strong electrical resistance which will act as a dielectric towards the outermost zones 11,111 containing the non orientated oxides, so as to give said path 9 the desired function of conductor of the electrical charges and to be electrically insulated from the surface on which said path 9 has been applied and made.

The polarisation process described above may be performed with modest voltages and variable frequencies and with limited times if intervening on the surface VM when the layer 2 is still in the polymerisation or hardening phase, in that, both from an electronic and physical point of view the particles of oxide with any graphite may be magnetised and orientated more easily and more easily migrate from the zones 10,110 to the zone 9 directly affected by the electromagnetic polarisation field induced by the head 5,6 of the polariser P.

It is however understood that for the same frequency, using a greater magnetising field than that indicated above, it will be possible to make said electrical conductor paths 9 on the intermediate layer 2 of the multilayer paint VM, even when said paint has dried or polymerised. With the varying of the voltage and different frequencies of the polariser P it is possible to generate in a single active layer 2 multi-paths extending at different depths in the layer 2, since each of these is generated with a different variation of the values and frequencies of the generator P.

By connecting sockets and/or other suitable means to the conductor path 9, as indicated schematically by the arrows 12 and 112 in FIG. 4, electrical charges in the form of current or signals can be transported from one zone to another of the same path 9.

Using the aforesaid polariser P (or a Laser) with voltages and polarisation frequencies variable to the magnitude of Gigahertz, it is believed possible to also transport image signals along the path 9. Even though in this first part of the project it was thought that weak currents and voltages were to be transported along said path 9, the method described of thickening the layers 1 and 3 of paint makes it possible to create appropriate safety impedance insulations against dispersions and electric shock, normally established in the range of 30 mA to 50 Hz.

Clearly the polarisation of the oxides in the layer 2 does not entail a mechanical molecular movement but merely a different state of excitation of the molecules. For an analogy refer to FIG. 5 which shows the layer 2 in vertical cross-section. The molecules M are for example a metallic oxide and the dopant D is a graphite, or the molecule M is a polymer (e.g. Thiophene or Butadiene) and the dopant D a metallic oxide. Depending on the composition of the matrix in the layer 2 there may be an exchange of roles and percentages in weight.

The action of the electromagnetic radiation R (with Laser or electromagnetic field generated by an air gap) is to energise or de-energise the molecules M sending the right energy according to the equation Energy=h*v. When they are energised (the dotted line marked E) their electronic status changes and they become conductors.

Visually one might imagine that conductive “bridges” are created between all the molecules M positioned in an orderly manner in sequence. For example when the molecule M is the polymer in the state of rest it behaves like a dielectric. With the arrival of energy an electron is ousted from the molecule M of the polymer, which becomes an ion and conducts.

The ousted electron orbits inside a decentralised electronic cloud.

With the energised molecules in the E state, an external circuit CR which includes the energised section of layer 2 is closed, and enables circulation of current.

A subsequent radiation R pours energy onto the energised molecule E. In the case of the aforesaid oxides, these place themselves in an unstable state from which they escape by reacquiring their original configuration as an insulator. If the molecule E is the polymer, more energy is not sufficient to return it to the state of dielectric but affine elements D are needed, atomically very close, which trap the ousted electron and return it to the polymer when the energy of anti-polarisation arrives (the molecule of the polymer is therefore functionalised by the element D). An element suitable for such purpose is quartz, but other materials may be used for such purpose.

With surface impedance values at least on the outer layer 3 to the magnitude of at least 20 KOhm, the necessary protection for a current within the aforesaid regulatory values is ensured. Thicknesses to the magnitude of 0.3-0.5 mm of the layer 3, are able to offer the necessary guarantees of insulation and safety for the user against the transit of current in the path 9 of several tens of amperes, at the nominal mains voltage and frequency, with the possibility of transporting both direct and alternate current.

It should be specified that on the same intermediate layer of paint 2, e.g. with metallic oxides and any graphite, several conductor paths 9 may be made, even in a single application, modifying the working frequency and voltage of the head of the polariser P, suitably structured for such purpose, and such paths or zones may have any relative arrangement, even crossed over, (that is they are positioned on parallel planes and in dissimilar directions even crossing over.

The chlorides described have the function of accelerating the passage between the transitions of state of the molecules M and E, avoiding hysteretic phenomena which would result in a very low response speed.

Lastly, it should be specified that within the scope of the invention there is also the possibility of using several layers of paint on top of each other and repeated so as to form a wafer with several conductor layers 2 e.g. of metallic oxides with any graphite, electrically insulated from each other by the layers 3, which said electrical conductor paths or zones 9 can be made on, in any relative arrangement, even overlapping and/or crossing over.

Where required, a nano-structured quartz-based filler, or in any case of suitable dimensions for the service required, may be loaded in the mixture of paint loaded with metallic oxides (and any graphite), optionally surface-treated with ferric chloride or ferric perchloride or aluminium chloride.

The said polymers, especially Thiophene and Butadiene are put in the mixture together with the quartz. Remember however that it is possible to use metallic oxides and/or polymers singly.

In particular the paint mixture may be loaded with the metallic oxides or even with just one or more of said polymers, preferably Thiophene, and a quartz-based filler (one or more of its 19 families), in particular BaTiO₃ or PbTiO₃. A component with TiO₃ has the advantage of being very adhesion-effective, does not dry and is able to make free electrons available with little energy.

The aforesaid mixture with quartz, as well as providing a polarisable state (that is, selectively alterable in its conductive capacity by external radiation) acquires unique piezoelectric properties, given to it by the specific nature of quartz.

This makes it possible to generate signals or current in situ on said paint compressing it with a finger or element or weight FG (see FIG. 6) or other system (the surface involved in this function may usefully be visualised externally by appropriate drawings).

In the layer 2 quartz of different particle sizes is preferably dispersed. One, indicated by Q1, is very fine, with particle dimensions at most of 20 nm, the other Q2 is larger with dimensions ranging from 600-700 nm to about 1 μm. In general a particle size with at least one order of magnitude of difference between Q1 and Q2 may be chosen.

Q1 is basically used as a carrier of charges towards the polymer and to promote the changes of the energised state, Q2 as a voltage/current generator.

When a quartz is pressed it generates an impulse of current (like a condenser in discharge), and the same is true for the Q2 dispersed in the layer 2. Then, by means of the thrust of the object FG, a current is generated which spreads through the layer 2.

In general two possibilities then exist. If the molecules M in the layer 2 (e.g. Thiophene) are energised (E state) and therefore conductive, the current is collected by them and channelled outwards via a circuit CR. If however the molecules M are in the de-energised state (and therefore not conductive) the electronic state reassembles in equilibrium without external effects.

Note the different function of the quartz Q1 and Q2.

The quartz Q1, replaceable by a functionally analogous element (e.g. chlorides lowering the hysteresis of electronic communication), is used as a functionalising element to electronically dialogue with the Thiophene, that is to say that it acts as a transport vehicle for the charges, without which the Thiophene would remain electrically inert or non-de-energisable. Another advantage is that the Q1 makes the final compound oily and does not allow it to dry.

The quartz Q2 acts only as a voltage/current generator but does not depend on Q1. The quartz Q2 is used both to generate electrical charges when subjected to mechanical pressure and to vibrate when given an electric impulse by means of the energised polymer chain E.

One can see then how the polarisation of the molecules M, similarly to what was said above, makes it possible to control the generation of current by the layer 2, like a switch.

The continuous pressure of the object FG does not generate current ad infinitum but solely an impulse. By pressing and releasing the layer 2 periodically a pulsating current is generated. If for example the pressing object FG shifts on the surface of the layer 2, it lends a movable force to the dispersed quartz Q1. So each local zone subject to stress in the layer 2 generates current, recharging when the stress is terminated.

In particular a spatially variable pressure on the layer 2 generates impulses of current locally which may sum together to give an almost continuous total current.

Think of painting a road. A vehicle in transit acts as a mobile presser FG on the layer 2. Each micro-section of the paint is first pressed by the vehicle and then released. At each pressure the micro-section generates an impulse of current. The layer 2 needs only be connected to an external circuit CR (FIG. 6) to collect the sum of all the impulses, that is electric power practically free.

Note how easy it is to define the current outputs from the layer 2 by merely creating for them a predefined path by means of the polarisation as above. In the same way the flow can be interrupted by depolarising a section of layer 2.

The invention thus makes it possible to generate pushbuttons, keys, cursors, alphanumerical keyboards or other means to operate directly from above the paint, since the electric signal generated by the mechanical pressure on the zone outwardly marked by the paint will travel, by the same programming logic already seen, along the path assigned to it by the polarisation of the metallic oxide fillers with any graphite.

The quartz Q2 in the layer 2 can also be used for a mechanical action.

When the layer 2 is polarised the molecules E are able to transfer charges to the quartz Q2 which would otherwise remain insulated in the matrix. By powering the layer 2 from outside with alternate electric voltage, the quartz Q2 can be selectively energised to make it vibrate at the imposed frequency.

A surprising consequence is that vibration-generating areas can be designed at will on the paint (by means of polarisation). Alternatively, or additionally, the vibration can be activated in areas chosen at will by having an electrical energisation available for the quartz.

Think for instance of coating the keel of a boat with the paint (or layer 2). Not only could the wave motion generate electricity by the effect described above (periodic motion of the wave=periodic pressure on the layer 2=current coming out of the layer 2), but by supplying electricity to the layer 2 with suitable frequency the layer 2 would vibrate upon contact with the water, in points or areas easily programmable by means of prior polarisation. The vibration makes the water detach from the keel and the boat would move much faster.

Lastly, the variation according to which the layer 2 having metallic oxides and/or polymers (e.g. Thiophene) with any graphite and/or quartz (corresponding to the quartz Q1 described) rather than being made in the form of a layer of paint, can be prepared in the form of a coloured or transparent plastic film, with said metallic oxides and with any graphite and/or quartz, applicable using adhesive means to the base layer of paint, if necessary already polarised, and coverable with said layer of finishing paint also falls within the scope of the invention.

1. Compound comprising:
a substrate of solvent, and
a dispersion in the substrate comprising
(i) a polymer with double covalent conjugated bond, that is to say a heterocyclic compound formed of n atoms of carbon and an atom of a different type linked in a loop structure; and
(ii) functionalising elements of the polymer, so that the state of the polymer changes from insulator to conductor and vice versa when struck by an electromagnetic field.

2. Compound according to claim 1, wherein the polymer comprises thiophene and/or butadiene.

3. Compound according to claim 1, wherein the dispersion comprises a graphite, in particular graphene and/or fullerene.

4. Compound according to claim 1, wherein the dispersion comprises quartz.

5. Compound according to claim 4, wherein the dispersion comprises:
(i) particles of quartz functionalising the polymer, and
(ii) particles of quartz adapted to donate or receive electrical charges to/from the substrate by piezoelectric effect.

6. Compound according to claim 5, wherein the dispersion comprises BaTiO₃ or PbTiO₃ or an element with group TiO₃.

7. Compound according to claim 5, wherein the dispersion of functionalising quartz has a particle size at most of 20 nm, and/or the donator/receiver quartz of electrical charges has a particle size ranging from 600-700 nm to about 1 μm.

8. Compound according to claim 1, wherein the solvent comprises benzene, in particular dichlorobenzene or dichloromethane.

9. Compound according to claim 1, wherein the solvent comprises a vinyl-acetate or vinyl esther base.

10. Compound according to claim 1, wherein the dispersion comprises ferric chloride or aluminium chloride, with or without colour pigments.

11. Method of making conductor circuits of electrical charges on any surface, characterised by the following steps:
applying a compound as in claim 1 to the surface of a layer,
polarising or pre-polarising paths or zones of the compound by means of an electromagnetic field adapted to transport to the polymer energy packets modifying its electrical resistance, from insulator to conductor and vice versa.

12. Method according to claim 11, wherein a Laser is used to generate the electromagnetic field.

13. Method according to claim 11, wherein conductor paths are made on various parallel planes at different depths in the substrate varying the frequency and/or intensity of the electromagnetic field.

14. Method according to claim 11, wherein an adhesion enhancing layer is deposited on the surface to which said layer of the compound is applied.

15. Method according to claim 11, wherein a finishing layer is applied over said layer of the compound.

16. Method according to claim 11, wherein said layer of the compound is applied by spraying or using a roller.

17. Film applicable to a surface comprising a layer comprising the compound defined in claim 1.

18. Method of generating signals or currents, comprising
applying a pressure to the compound as in claim 4,
bringing the charge generated inside the compound outside by means of conductor paths obtained by polarisation in the compound.

19. Method according to claim 18, wherein a discontinuous or alternate or periodic pressure is applied.

20. Method according to claim 18, wherein
the compound is applied to the surface of a road or practicable passage,
the passage of the vehicle or pedestrian in transit is used as a presser element of the compound; and
current impulses are collected from the compound.

21. Method according to claim 18, wherein
a zone functioning as a pushbutton, or key or alphanumerical keyboard is made with a compound comprising:
a substrate of solvent, and
a dispersion in the substrate comprising
(i) a polymer with double covalent conjugated bond, that is to say a heterocyclic compound formed of n atoms of carbon and an atom of a different type linked in a loop structure; and
(ii) functionalising elements of the polymer, so that the state of the polymer changes from insulator to conductor and vice versa when struck by an electromagnetic field; and
the signal relative to the electrical charge generated by a mechanical pressure exerted on the zone is processed.

22. Method according to claim 18, wherein the compound is applied to the hull of a boat and the wave motion is used as a pressing agent to generate electrical power.

23. Area functioning as a pushbutton, or key or alphanumerical keyboard comprising a layer of compound according to claim 4.

24. Method of making a surface vibrate, comprising
supplying the compound according to claim 4 applied to the surface and made conductive by means of polarisation from outside with an alternate electrical energisation.

25. Method according to claim 24, wherein the compound is applied to the hull of a boat; and
alternate electric power is supplied to the compound to make it vibrate near the water so that the vibration makes the water detach from the hull.
